(19) United States
(12) Patent Application Publication
(10) Pub. No.: US 2025/0044332 A1
(43) Pub. Date: Feb. 6, 2025

(54) HIGH-FREQUENCY COMPONENT TEST DEVICE AND METHOD THEREOF

(71) Applicant: INDUSTRIAL TECHNOLOGY RESEARCH INSTITUTE, Hsinchu (TW)

(72) Inventors: Sih-Han LI, New Taipei City (TW); Jie ZHANG, New Taipei City (TW); Peng-I MEI, Ji’an Township (TW)

(73) Assignee: INDUSTRIAL TECHNOLOGY RESEARCH INSTITUTE, Hsinchu (TW)

(21) Appl. No.: 18/921,460

(22) Filed: Oct. 21, 2024

Related U.S. Application Data
(63) Continuation-in-part of application No. 17/559,371, filed on Dec. 22, 2021, now Pat. No. 12,163,989.
(60) Provisional application No. 63/179,597, filed on Apr. 26, 2021.

(30) Foreign Application Priority Data
Nov. 11, 2021 (TW) 110142087

(51) Int. Cl. G01R 27/28; G01R 31/28; G01R 35/00

(52) U.S. Cl. CPC G01R 27/28; G01R 31/2822; G01R 35/005

(57) ABSTRACT

A high-frequency component test device including a test key and a test module is provided. The test key includes a front-level key and a back-level key which are arranged symmetrically and have the same electrical length and characteristic impedance. The test module is used to measure an S parameter of the front-level key and the back-level key connected directly and an S parameter of a structure where a device under test (DUT) is added between the front-level key and the back-level key. The test module performs S parameter calculation in the frequency domain and converts the S parameter into an ABCD parameter matrix, and then obtains an ABCD parameter of a de-embedded DUT using a matrix root-opening operation and an inverse matrix operation.

This application is a continuation-in-part (CIP) application of application Ser. No. 17/559,371, filed Dec. 22, 2021, which claims the benefits of U.S. provisional application Ser. No. 63/179,597, filed Apr. 26, 2021 and Taiwan application Serial No. 110142087, filed Nov. 11, 2021, the subject matters of which are incorporated herein by reference.

### BACKGROUND

### Technical Field

The disclosure relates in general to a test device, and more particularly to a high-frequency component test device and a test method thereof.

### Description of the Related Art

Conventional measurement and calibration of a high-frequency component mainly uses SOLT or TRL. SOLT requires four calibration kits including short, open, thru and load kits. TRL requires three set of test keys including thru, reflect and line keys. The above calibration technologies normally use different calibration methods in response to specific measurement requirements (such as broadband frequency or on-wafer probing), making the calibration steps more complicated.

Additionally, the calibration result of the calibration method using SOLT or TRL may easily be affected by the error generated in each measurement. For example, the calibration result will be affected when the probing depth differs or when the probing position is offset. Therefore, it has become a prominent task for the industries to provide a solution capable of avoiding inaccurate measurement of the device under test (DUT) caused by calibration error.

### SUMMARY

The disclosure is directed to a high-frequency component test device and a method thereof capable of reducing calibration error.

According to one embodiment of the present disclosure, a high-frequency component test device including a first test key and a test module is provided. The first test key includes a first front-level key and a first back-level key which are arranged symmetrically and have the same electrical length and characteristic impedance. The test module is used to measure an S parameter of the front-level key and the back-level key connected directly and an S parameter of a tested structure where a device under test (DUT) is added between the front-level key and the back-level key, wherein the test module performs S parameter calculation in a frequency domain and converts the S parameter into an ABCD parameter matrix, and then obtains an ABCD parameter of a de-embedded DUT using a matrix root-opening operation and an inverse matrix operation.

According to another embodiment of the present disclosure, a high-frequency component test method is provided. The high-frequency component test method includes the following steps. A test key including a front-level key and a back-level key is provided, wherein the front-level key and the back-level key are arranged symmetrically and have the same electrical length and characteristic impedance. An S parameter of the front-level key and the back-level key connected directly and an S parameter of a structure where a device under test (DUT) is added between the front-level key and the back-level key are measured. The S parameter calculation is performed in the frequency domain and the S parameter is converted into an ABCD parameter matrix, and then an ABCD parameter matrix of the front-level key and the back-level key is obtained using a root-opening operation. An ABCD parameter of a de-embedded DUT is calculated according to an inverse matrix of the ABCD parameter matrix of the front-level key and the back-level key.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIGS. 1 and 2 respectively are schematic diagrams of a high-frequency component test device according to an embodiment of the present disclosure;

FIG. 3 is a flowchart of a high-frequency component test method according to an embodiment of the present disclosure; and

FIGS. 4A-4D respectively are schematic diagrams illustrating characteristic verification of a high-frequency component test device according to an embodiment of the present disclosure.

FIGS. 5 and 6 respectively illustrate schematic diagrams of a high-frequency component test device according to another embodiment of the present disclosure.

FIGS. 7 and 8 respectively illustrate schematic diagrams of the second test key and the third test key used in the high-frequency component test device.

FIG. 9 illustrates a flow chart of a high-frequency component test method according to an embodiment of the present disclosure.

### DETAILED DESCRIPTION

Technical solutions for the embodiments of the present disclosure are clearly and thoroughly disclosed with accompanying drawings. Obviously, the embodiments disclosed below are only some rather than all of the embodiments of the present disclosure. Besides, the disclosed features, structures or characteristics can be combined in one or more embodiments in any suitable way. In the following disclosure, many detailed descriptions are provided for the embodiments of the present disclosure to be better and fully understood. However, anyone ordinarily skilled in the art of the disclosure will understand that technical solution for the present disclosure can be implemented without one or some of the specific details disclosed below or can be implemented using other methods, devices, or steps. In some circumstances, generally known methods, devices, implementations, or operations of the technical solution capable of implementing the present disclosure are not necessarily illustrated or disclosed in greater details lest the aspects of the present disclosure might be distracted.

In the present embodiment, high-frequency performance of a device such as a radio frequency emitter or a microwave device is represented by a scattering parameter (S parameter). The current S parameter test device generates a large parasitic effect, so that the S parameter obtained by an under-test high-frequency component cannot correctly represent the performance of the high-frequency component. Thus, a test key is disposed on the test device of the present embodiment to define a de-embedded plane 101 of the high-frequency component, that is, the plane between the intrinsic component (DUT 102) and the parasitic component (test device 100) as indicated in FIG. 2. By removing the parasitic effect generated by the test device in a high-frequency working state, an accurate intrinsic transmission parameter will be obtained.

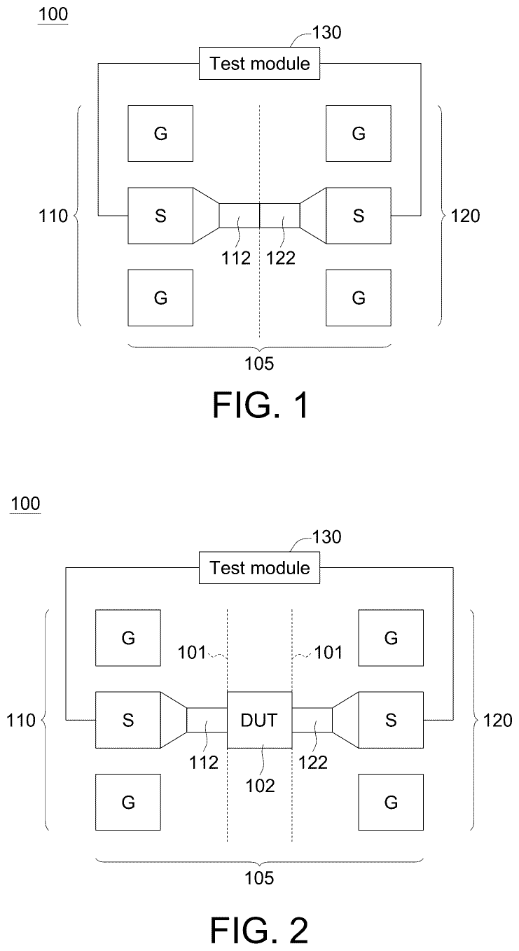

Referring to FIGS. 1 and 2, schematic diagrams of a high-frequency component test device 100 according to an embodiment of the present disclosure are respectively shown. In FIG. 1, the high-frequency component test device 100 includes a test key 105 and a test module 130. The test key 105 includes a front-level key 110 and a back-level key 120. The front-level key 110 and the back-level key 120 are symmetrically arranged and have the same electrical length and characteristic impedance. In an embodiment, the front-level key 110 and the back-level key 120 exemplarily have a characteristic impedance of 50Ω, but the present disclosure is not limited thereto. The front-level key 110 and the back-level key 120 can be disposed according to a ground-signal-ground (GSG) configuration. In another embodiment, the front-level key 110 and the back-level key 120 are disposed by a ground-signal (GS) configuration, a ground-signal—ground-signal-ground (GSGSG) configuration or other suitable test configuration. The test module 130 can be a network analyzer.

The front-level key 110 includes a first transmission line 112. The back-level key 120 includes a second transmission line 122. The first transmission line 112 and the second transmission line 122 have the same electrical length and material, such that the transmission parameters on the two sides of the front and the rear are substantially identical. In FIG. 2, the DUT 102 is connected between two transmission lines 112 and 122. A de-embedded plane 101 is respectively formed between the DUT 102 and the first transmission line 112 and between the DUT 102 and the second transmission line 122 (the de-embedded plane 101 is perpendicular to the paper surface), such that the DUT 102 is connected between two de-embedded planes 101. The left-hand structure and the right-hand structure of the de-embedded plane 101 respectively have an intrinsic transmission parameter. The intrinsic transmission parameter of the DUT 102 can be estimated according to the intrinsic transmission parameters of the left-hand structure and the right-hand structure and the transmission parameter of the structure under test. In an embodiment, the intrinsic transmission parameter is represented by an ABCD parameter, for example.

In the present embodiment, the parameter conversion module converts the S parameter into an ABCD parameter, wherein when the front-level key 110 and the back-level key 120 are connected directly, the S parameter can be represented by an ABCD parameter, such as parameter matrix

$$[ \begin{matrix}A & B \\ C & D\end{matrix} ] .$$

For example, when the front-level key 110 and the back-level key 120 are connected directly, a total voltage V1 and a total current 11 are inputted to one end of the two-port network, and a total voltage V2 and a total current 12 are outputted from the other end of the two-port network, wherein V1=AV2+BI2, 11=CV2+DI2, that is,

$$[ \begin{matrix}{V}_{1} \\ {I}_{1}\end{matrix} ] = [ \begin{matrix}A & B \\ C & D\end{matrix} ] [ \begin{matrix}{V}_{2} \\ {I}_{2}\end{matrix} ] ,$$

wherein the relationship among the input voltage V1, the output voltage V2, the input current 11 and the output current 12 is represented by parameters A, B, C and D.

The test module 130 of the present embodiment can obtain the ABCD parameter of the front-level key 110 and the back-level key 120 according to a root-opening operation of the ABCD parameter matrix, and the calculation formula (1) can be expressed as: [Dem]=[PAD][PAD], wherein [PAD] is an ABCD parameter matrix of the front-level key 110 and the back-level key 120; [Dem] is an ABCD parameter matrix when the front-level key 110 and the back-level key 120 are connected directly. In the present embodiment, since the front-level key 110 and the back-level key 120 have the same electrical length and characteristic impedance, the front-level key 110 and the back-level key 120 have the same ABCD parameter matrix. Therefore, the ABCD parameter matrix [PAD] of the front-level key 110 and the back-level key 120 can be obtained by performing a root-opening operation on the ABCD parameter matrix [Dem] of the two directly connected keys 110 and 120 according to formula (1): [PAD]=\sqrt{[Dem]}.

Also, refer to FIG. 2. When a device under test (DUT) 102 is added between the front-level key 110 and the back-level key 120, the test module 130 measures the S parameter of the structure under test where the DUT 102 is added between the front-level key 110 and the back-level key 120. Then, the test module 130 converts the S parameter into an ABCD parameter, and then obtains the ABCD parameter of a de-embedded DUT 102 according to an inverse matrix. The calculation formula (2) is expressed as: [DUT]=[PAD][Golden][PAD], wherein [Golden] is an ABCD parameter matrix of the de-embedded DUT 102; [DUT] is an ABCD parameter matrix when the front-level key 110 and the back-level key 120 are directly connected to the DUT 102. Based on formula (2), [Golden]=[PAD]⁻¹ [DUT][PAD]⁻¹, wherein [PAD]-1 is an inverse matrix of the ABCD parameter matrix of the front-level key 110 and the back-level key 120, that is, [PAD]⁻¹=(\sqrt{˜[Dem]})⁻¹.

In the present embodiment, with only one set of de-embedded test keys, the high-frequency component test device 100 can remove the parasitic effect of extra layout and tracing caused by measurement, not only increasing the de-embedded test speed and accuracy but also reducing probing error.

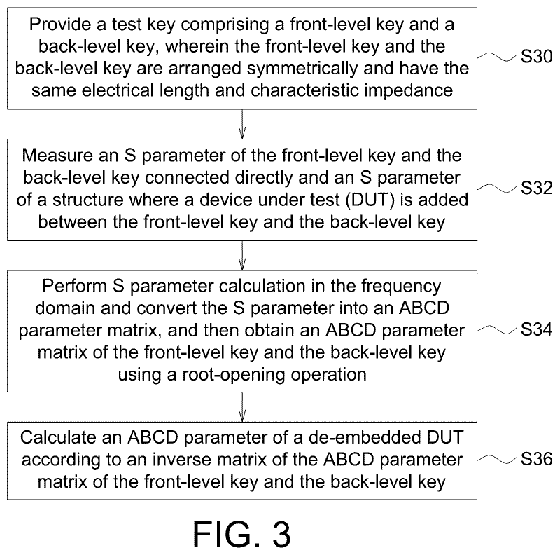

Refer to FIGS. 1-3. FIG. 3 is a flowchart of a high-frequency component test method according to an embodiment of the present disclosure. Firstly, in step S30, a test key 105 comprising a front-level key 110 and a back-level key 120 is provided, the front-level key 110 and the back-level key 120 are arranged symmetrically and have the same electrical length and characteristic impedance. In step S32, an S parameter of the front-level key 110 and the back-level key 120 connected directly and an S parameter of a structure where a device under test (DUT) 102 is added between the front-level key 110 and the back-level key 120 are measured. In step S34, the S parameter calculation is performed in the frequency domain and the S parameter is converted into an ABCD parameter matrix, and then an ABCD parameter matrix of the front-level key 110 and the back-level key 120 is obtained using a root-opening operation. In step S36, an ABCD parameter of a de-embedded DUT 102 is calculated according to an inverse matrix of the ABCD parameter matrix of the front-level key 110 and the back-level key 120.

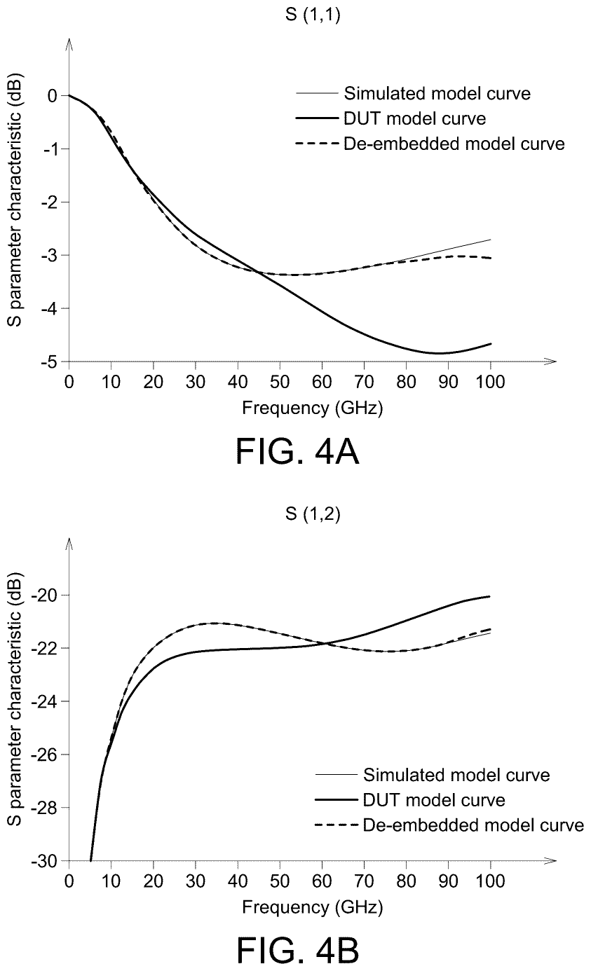

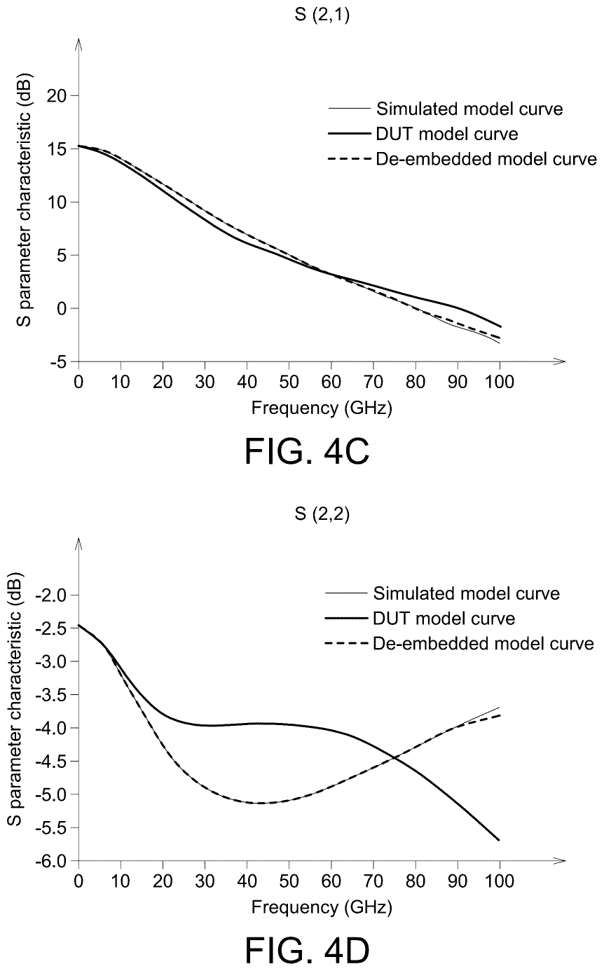

Referring FIGS. 4A-4D, schematic diagrams illustrating characteristic verification of S parameter of a high-frequency component test device 100 according to an embodiment of the present disclosure are respectively shown. In FIG. 4A, S(1,1) parameter is an input reflection coefficient, that is, an input return loss. In FIG. 4B, S(1,2) parameter is a reverse transmission coefficient, that is, isolation. In FIG. 4C, S(2,1) parameter is a forward transmission coefficient, that is, gain. In FIG. 4D, S(2,2) parameter is an output reflection coefficient, that is, an output return loss. In the present embodiment, feasibility and characteristic verification of S parameter are verified using simulation, and a comparison between the simulated model curve, DUT model curve and de-embedded model curve shows that an intrinsic transmission parameter close to the DUT 102 can be obtained using the de-embedded procedure of the present embodiment. Simulation is performed until the error in the curve fitting of 100 GHz small signal is less than 10%. In another embodiment, when the verification is performed using the transmission key and the test key, simulation is performed until the error in the characteristic impedance Z0 and transmission line length BL of the 67 GHz small signal phase can be less than 8%.

According to the high-frequency component test device and the test method thereof disclosed in above embodiments of the present disclosure, only one test key is used as calibration kit, the front-level key and the back-level key of the test key have the same electrical length and characteristic impedance, the characteristic impedance is 50Ω being the same as the impedance of the probe, hence avoiding inaccurate measurement of the DUT caused by calibration error. In comparison to the conventional measurement and calibration of a high-frequency component which mainly use SOLT or TRL, the method of the present embodiment can reduce calibration steps and remove the parasitic effect generated by the test device in a high-frequency working state, so as to obtain an accurate S parameter.

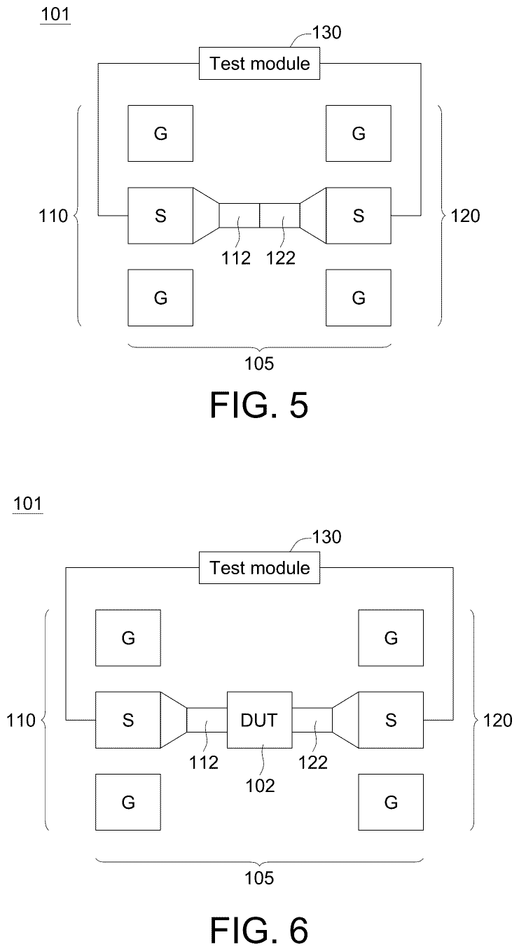

Referring to FIGS. 5 and 6, schematic diagrams of a high-frequency component test device 101 according to another embodiment of the present disclosure are respectively shown. In FIG. 5, the high-frequency component test device 101 includes a first test key 105 and a test module 130. The first test key 105 includes a first front-level key 110 and a first back-level key 120. The first front-level key 110 and the first back-level key 120 are symmetrically arranged and have the same electrical length and characteristic impedance. In an embodiment, the first front-level key 110 and the first back-level key 120 exemplarily have a characteristic impedance of 50Ω, but the present disclosure is not limited thereto. The first front-level key 110 and the first back-level key 120 can be disposed according to GSG configuration, GSGSG configuration or other suitable test configuration. The test module 130 can be a network analyzer.

The first front-level key 110 may include a first transmission line 112. The first back-level key 120 may include a second transmission line 122. The first transmission line 112 and the second transmission line 122 have the same electrical length and material, such that the transmission parameters on the two sides of the front and the rear are substantially identical. In FIG. 6, the DUT 102 is connected between the first front-level key 110 and the first back-level key 120. The intrinsic transmission parameter of the DUT 102 can be estimated according to the intrinsic transmission parameters of the left-hand structure and the right-hand structure and the transmission parameter of the tested structure. In an embodiment, the intrinsic transmission parameter is represented by an ABCD parameter, for example.

In the present embodiment, the parameter conversion module converts the S parameter into an ABCD parameter, wherein when the first front-level key 110 and the first back-level key 120 are connected directly, the S parameter can be represented by an ABCD parameter, such as parameter matrix

$$[ \begin{matrix}A & B \\ C & D\end{matrix} ] .$$

For example, when the first front-level key 110 and the first matrix back-level key 120 are connected directly, a total voltage V1 and a total current 11 are inputted to one end of the two-port network, and a total voltage V2 and a total current 12 are outputted from the other end of the two-port network, wherein V1=AV2+BI2, 11=CV2+DI2, that is,

$$[ \begin{matrix}{V}_{1} \\ {I}_{1}\end{matrix} ] = [ \begin{matrix}A & B \\ C & D\end{matrix} ] [ \begin{matrix}{V}_{2} \\ {I}_{2}\end{matrix} ] ,$$

wherein the relationship among the input voltage V1, the output voltage V2, the input current 11 and the output current 12 is represented by parameters A, B, C and D.

The test module 130 of the present embodiment can obtain the ABCD parameter of the first front-level key 110 and the first back-level key 120 according to a root-opening operation of the ABCD parameter matrix, and the calculation formula (1′) can be expressed as: [Dem1]=[PAD] [PAD], wherein [PAD] is an ABCD parameter matrix of the first front-level key 110 and the first back-level key 120; [Dem1] is an ABCD parameter matrix when the first front-level key 110 and the first back-level key 120 are connected directly. In the present embodiment, since the first front-level key 110 and the first back-level key 120 have the same electrical length and characteristic impedance, the first front-level key 110 and the first back-level key 120 have the same ABCD parameter matrix. Therefore, the ABCD parameter matrix [PAD] of the first front-level key 110 and the first back-level key 120 can be obtained by performing a root-opening operation on the ABCD parameter matrix [Dem1] of the two directly connected keys 110 and 120 according to formula (1′), and is expressed as, [PAD]=\sqrt{[Dem1]}.

Also, refer to FIG. 6. When a device under test (DUT) 102 is added between the first front-level key 110 and the first back-level key 120, the test module 130 measures the S parameter of the structure where the DUT 102 is added between the first front-level key 110 and the first back-level key 120. Then, the test module 130 converts the S parameter into an ABCD parameter, and then obtains the ABCD parameter of a de-embedded DUT 102 according to an inverse matrix. The calculation formula (2) is expressed as: [DUT]= [PAD] [Golden] [PAD], wherein [Golden] is an ABCD parameter matrix of the de-embedded DUT 102; [DUT] is an ABCD parameter matrix when the first front-level key 110 and the first back-level key 120 are directly connected to the DUT 102. Based on formula (2), [Golden]=[PAD]⁻¹ [DUT][PAD]⁻¹ is obtained, wherein [PAD] 1 is an inverse matrix of the ABCD parameter matrix of the first front-level key 110 and the first back-level key 120, that is, [PAD]⁻¹=(\sqrt{[Dem1]})⁻¹.

In one embodiment, the high-frequency component test device 101 uses the first test key 105 in the de-embedded test method to remove the parasitic effect of extra layout and tracing caused by measurement, not only increasing the de-embedded test speed and accuracy but also reducing probing error. In addition, the high-frequency component test device 101 also verifies whether the inverse matrix of the ABCD parameter matrix of the first front-level key 110 and the first back-level key 120 is correct by measuring the ABCD parameter matrix of the second test key 205 and the third test key 305 to correctly calculate the ABCD parameters of the de-embedded DUT 102.

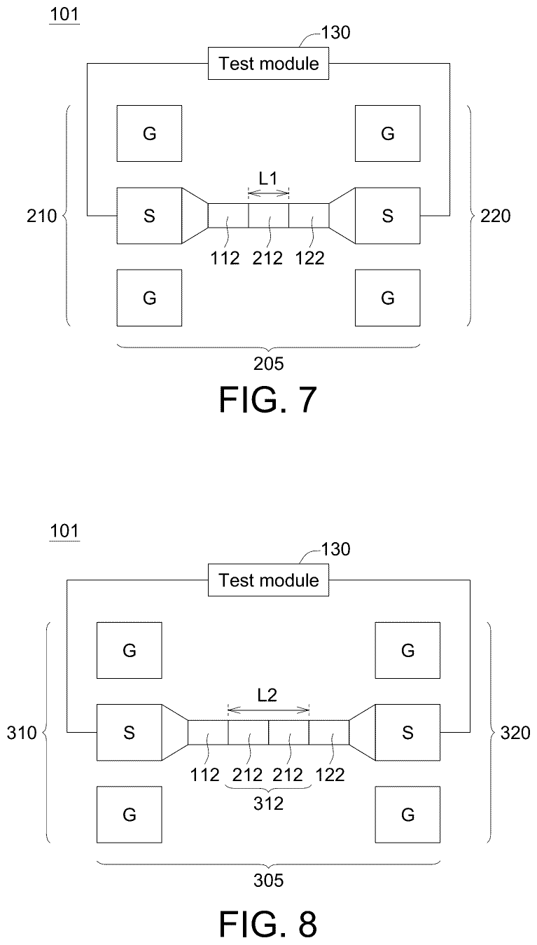

Referring to FIGS. 7 and 8, schematic diagrams of the second test key 205 and the third test key 305 used in the high-frequency component test device 101 are respectively illustrated. The second test key 205 includes a second front-level key 210, a first line segment 212 and a second back-level key 220 connected to each other. The second front-level key 210 and the second back-level key 220 have the same electrical length and characteristic impedance (e.g., 50 ohms). The second front-level key 210 and the second back-level key 220 are arranged, for example, according to GSG, GGSSG or other suitable test configurations. In addition, the third test key 305 includes a third front-level key 310, a second line segment 312 and a third back-level key 320 connected to each other. The third front-level key 310 and the third back-level key 320 have the same electrical length and characteristic impedance (e.g., 50 ohms). The third front-level key 310 and the third back-level key 320 are arranged, for example, according to GSG, GGSSG or other suitable test configurations.

In one embodiment, the first test key 105, the second test key 205 and the third test key 305 are, for example, coplanar waveguides (CPW) or microstrip lines respectively, and the transmission line of each of the first to third test keys has the same characteristic impedance (e.g., 50 ohms). In addition, the length L2 of the second line segment 312 is, for example, twice the length L1 of the first line segment 212, that is, L2=2*L1. In one embodiment, the second line segment 312 may be formed by two first line segments 212 connected to each other or may be composed of a single line segment.

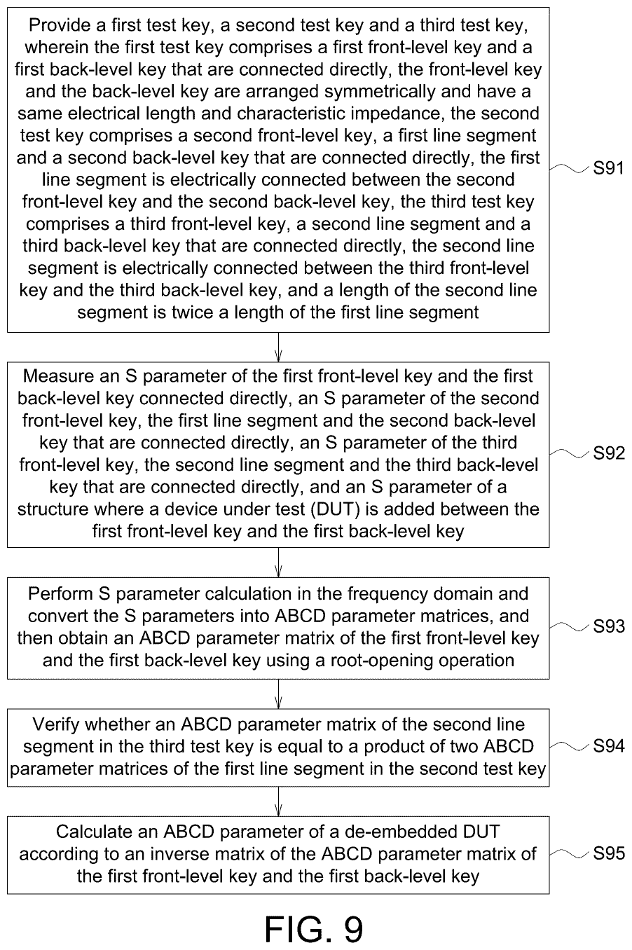

Refer to FIGS. 5 to 9. FIG. 9 illustrates a flow chart of a high-frequency component test method according to an embodiment of the present disclosure. First, in step S91, a first test key 105, a second test key 205 and a third test key 305 are provided. The first test key 105 includes a first front-level key 110 and a first back-level key 120 directly connected, the second test key 205 includes a second front-level key 210, a first line segment 212 and a second back-level key 220 that are directly connected. The first line segment 212 is electrically connected between the second front-level key 210 and the third back-level key 220. The third test key 305 includes a third front-level key 310, a second line segment 312 and a third back-level key 320 that are directly connected. The second line segment 312 is electrically connected between the third front-level key 310 and the third back-level key 320, and the length L2 of the second line segment 312 is twice the length L1 of the first line segment 212. In step S92, the S parameter of the first front-level key 110 and the first back-level key 120 directly connected is measured; the S parameter of the second front-level key 210, the first line segment 212 and the second back-level key 220 directly connected is measured; the S parameter of the third front-level key 310, the second line segment 312 and the third back-level key 320 directly connected is measured; and the S parameter of a structure where the DUT 102 is added between the first front-level key 110 and the first back-level key 120 is measured. In step S93, S parameter calculation is performed in the frequency domain and the S parameter of the first test key 105 is converted into an ABCD parameter matrix, and then the ABCD parameter matrix of the first front-level key 110 and the first back-level key 120 is obtained by using a root-opening operation, as described above, it can be obtained from formula (1′): [PAD]=\sqrt{[Dem1]}. In step S94, the S parameter of the second test key 205 is converted into an ABCD parameter matrix, the S parameter of the third test key 305 is converted into an ABCD parameter matrix, and whether the ABCD parameter matrix of the second line segment 312 in the third test key 305 is equal to the product of two ABCD parameter matrices of the first line segment 212 in the second test key 205 is verified. In step S95, the ABCD parameter of a de-embedded DUT 102 is calculated according to the inverse matrix of the ABCD parameter matrix of the first front-level key 110 and the first back-level key 120.

In step S94, [PAD] is an ABCD parameter matrix of the second front-level key 210 and the second back-level key 220, [Line1] is an ABCD parameter matrix of the first line segment 212, and [Dem2] is an ABCD parameter matrix of the second front-level key 210, the first line segment 212, and the second back-level key 220 that are directly connected, the calculation formula (3) is expressed as follows: [Dem2]=[PAD][Line1][PAD]. Based on the calculation formula (3), [Line1]=[PAD]⁻¹ [Dem2][PAD]⁻¹ is obtained, where [PAD]-1 is an inverse matrix of the ABCD parameter matrix of the second front-level key 210 and the second back-level key 220.

In addition, in step S94, [PAD] is an ABCD parameter matrix of the third front-level key 310 and the third back-level key 320, [Line2] is an ABCD parameter matrix of the second line segment 312, and [Dem3] is an ABCD parameter matrix of the third front-level key 310, the second line segment 312 and the third back-level key 320 that are directly connected, where the calculation formula (4) is expressed as follows: [Dem3]=[PAD][Line2][PAD]. Based on the calculation formula (4), [Line2]=[PAD]⁻¹ [Dem3][PAD]⁻¹ is obtained, where [PAD]⁻¹ is an inverse matrix of the ABCD parameter matrix of the third front-level key 310 and the third back-level key 320.

In step S94, when the test module 130 verifies that the ABCD parameter matrix of the second line segment 312 in the third test key 305 is equal to the product of the two ABCD parameter matrices of the first line segment 212, that is, [Line2]=[Line1][Line1] is satisfied, indicating that the inverse matrix [PAD]⁻¹ of the ABCD parameter matrix of the first front-level key 110 and the first back-level key 120 is correct. On the contrary, when [Line2]=[Line1][Line1] is not satisfied, indicating that the inverse matrix [PAD]-1 of the ABCD parameter matrix of the first front-level key 110 and the first back-level key 120 is incorrect, so that the ABCD parameter matrix of the de-embedding DUT 102 cannot be calculated correctly.

In step S95, [Golden] is the ABCD parameter matrix of the de-embedded DUT 102, and [DUT] is an ABCD parameter matrix of the first front-level key 110, the DUT 102 and the first back-level key 120 that are directly connected. The calculation formula (2) is expressed as follows: [DUT]=[PAD][Golden][PAD]. Based on the calculation formula (2), [Golden]=[PAD]⁻¹ [DUT][PAD]⁻¹ is obtained, where [PAD]⁻¹ is an inverse matrix of the ABCD parameter matrix of the first front-level key 110 and the first back-level key 120, that is, [PAD]⁻¹=(\sqrt{[Dem1]})⁻¹. When the inverse matrix [PAD] 1 of the ABCD parameter matrix of the first front-level key 110 and the first back-level key 120 is verified to be correct, the ABCD parameter matrix of the de-embedded DUT 102 can be correctly calculated.

The high-frequency component test device 101 of the present disclosure can avoid measurement inaccuracies of the DUT due to calibration errors through the above verification method. For example, under W-band operation (such as in the range of 75-110 GHZ), the calibration errors caused by different probing depths or probing position deviations can be prevented to have better measurement results for the DUT.

While the disclosure has been described by way of example and in terms of the preferred embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A high-frequency component test device, comprising:
a first test key, comprising a first front-level key and a first back-level key, wherein the front-level key and the back-level key are arranged symmetrically and have a same electrical length and characteristic impedance; and
a test module used to measure an S parameter of the first front-level key and the first back-level key connected directly and an S parameter of a tested structure where a device under test (DUT) is added between the first front-level key and the first back-level key, wherein the test module performs S parameter calculation in a frequency domain and converts the S parameter into an ABCD parameter matrix, and then obtains an ABCD parameter of a de-embedded DUT using a matrix root-opening operation and an inverse matrix operation.

2. The test device according to claim 1, further comprises a second test key, the second test key includes a second front-level key, a first line segment and a second back-level key that are directly connected, and the first line segment is electrically connected between the second front-level key and the second back-level key.

3. The test device according to claim 2, further comprises a third test key, the third test key includes a third front-level key, a second line segment and a third back-level key that are directly connected, the second line segment is electrically connected between the third front-level key and the third back-level key, and a length of the second line segment is twice a length of the first line segment.

4. The test device according to claim 3, wherein [PAD] is an ABCD parameter matrix of the first front-level key and the first back-level key, [Dem1] is an ABCD parameter matrix when the first front-level key and the first back-level key are connected directly, [Dem1]=[PAD][PAD], wherein the ABCD parameter matrix of the first front-level key and the first back-level key is expressed as: [PAD]=\sqrt{[Dem1]}.

5. The test device according to claim 4, wherein [PAD] is an ABCD parameter matrix of the second front-level key and the second back-level key, [Line1] is an ABCD parameter matrix of the first line segment, [Dem2] is an ABCD parameter matrix when the second front-level key, the first line segment and the second back-level key are directly connected, wherein [Dem2]=[PAD][Line1][PAD].

6. The test device according to claim 5, wherein [PAD] is an ABCD parameter matrix of the third front-level key and the third back-level key, [Line2] is an ABCD parameter matrix of the second line segment, and [Dem3] is an ABCD parameter matrix when the third front-level key, the second line segment and the third back-level key are directly connected, wherein [Dem3]=[PAD][Line2][PAD].

7. The test device according to claim 6, wherein the test module verifies that the ABCD parameter matrix of the second line segment in the third test key is equal to a product of two ABCD parameter matrices of the first line segment, and is expressed as [Line2]=[Line1][Line1].

8. The test device according to claim 7, wherein [Golden] is an ABCD parameter matrix of the de-embedded DUT, [DUT] is an ABCD parameter matrix when the first front-level key, the DUT, and the first back-level key are connected directly, [DUT]=[PAD][Golden][PAD], the ABCD parameter matrix of the de-embedded DUT is calculated according to an inverse matrix of the ABCD parameter matrix of the first front-level key and the first back-level key and is expressed as: [Golden]=[PAD]⁻¹ [DUT][PAD]⁻¹.

9. A high-frequency component test method, comprising:
providing a first test key, a second test key and a third test key, the first test key comprising a first front-level key and a first back-level key that are connected directly, wherein the front-level key and the back-level key are arranged symmetrically and have a same electrical length and characteristic impedance, the second test key comprising a second front-level key, a first line segment and a second back-level key that are connected directly, the first line segment being electrically connected between the second front-level key and the second back-level key, the third test key comprising a third front-level key, a second line segment and a third back-level key that are connected directly, the second line segment being electrically connected between the third front-level key and the third back-level key, wherein a length of the second line segment is twice a length of the first line segment;
measuring an S parameter of the first front-level key and the first back-level key connected directly, an S parameter of the second front-level key, the first line segment and the second back-level key that are connected directly, an S parameter of the third front-level key, the second line segment and the third back-level key that are connected directly, and an S parameter of a structure where a device under test (DUT) is added between the first front-level key and the first back-level key;
performing S parameter calculation in the frequency domain and converting the S parameters into ABCD parameter matrices, and then obtaining an ABCD parameter matrix of the first front-level key and the first back-level key using a root-opening operation;
verifying whether an ABCD parameter matrix of the second line segment in the third test key is equal to a product of two ABCD parameter matrices of the first line segment in the second test key; and
calculating an ABCD parameter of a de-embedded DUT according to an inverse matrix of the ABCD parameter matrix of the first front-level key and the first back-level key.

10. The test method according to claim 9, wherein the first test key, the second test key and the third test key have the same characteristic impedance.

11. The test method according to claim 9, wherein [PAD] is an ABCD parameter matrix of the first front-level key and the first back-level key, [Dem1] is an ABCD parameter matrix when the first front-level key and the first back-level key are connected directly, [Dem1]=[PAD][PAD], wherein the ABCD parameter matrix of the first front-level key and the first back-level key is expressed as: [PAD]=\sqrt{[Dem1]}.

12. The test method according to claim 11, wherein [PAD] is an ABCD parameter matrix of the second front-level key and the second back-level key, [Line1] is an ABCD parameter matrix of the first line segment, [Dem2] is an ABCD parameter matrix when the second front-level key, the first line segment and the second back-level key are directly connected, wherein [Dem2]=[PAD][Line1][PAD].

13. The test method according to claim 12, wherein [PAD] is an ABCD parameter matrix of the third front-level key and the third back-level key, [Line2] is an ABCD parameter matrix of the second line segment, and [Dem3] is an ABCD parameter matrix when the third front-level key, the second line segment and the third back-level key are directly connected, wherein [Dem3]=[PAD][Line2][PAD].

14. The test method according to claim 13, wherein it is verified that the ABCD parameter matrix of the second line segment in the third test key is equal to a product of two ABCD parameter matrices of the first line segment, and is expressed as [Line2]=[Line1][Line1].

15. The test method according to claim 14, wherein [Golden] is an ABCD parameter matrix of the de-embedded DUT, [DUT] is an ABCD parameter matrix when the first front-level key, the DUT and the first back-level key are directly connected, [DUT]=[PAD][Golden][PAD], the ABCD parameter matrix of the de-embedded DUT is calculated according to an inverse matrix of the ABCD parameter matrix of the first front-level key and the first back-level key and is expressed as [Golden]=[PAD]⁻¹ [DUT] [PAD]⁻¹.
